(19) United States
(12) Patent Application Publication
(10) Pub. No.: US 2010/0123508 A1
(43) Pub. Date: May 20, 2010

(54) SMOOTH SWITCHING BETWEEN ANALOG INPUT SIGNALS

(75) Inventors: Gang Zha, Shenzhen (CN); Guenter Neidhardt, Munich (DE); Peter Kirchlechner, Munich (DE)

Correspondence Address: STMICROELECTRONICS, INC., MAIL STATION 2346, 1310 ELECTRONICS DRIVE, CARROLLTON, TX, 75006, US

(73) Assignees: STMicroelectronics (Shenzhen) R&D Co. Ltd., Shenzhen (CN); STMicroelectronics Design & Application GmbH, Grasbrunn (DE)

(21) Appl. No.: 12/578,572

(22) Filed: Oct. 13, 2009

(30) Foreign Application Priority Data
Nov. 14, 2008 (CN) 200810176191.1

(51) Int. Cl. H03K 17/00

(52) U.S. Cl. 327/408; 327/407

(57) ABSTRACT

A first switching circuit has an input for receiving a first input signal, and a second switching circuit has an input for receiving a second input signal. A node is connected to receive outputs from both the first and second switching circuits. A filter receives an unfiltered signal from the node to generate an output signal. A circuit is provided to alternately actuate the first and second switching circuits during a transition time period so as to smoothly transition the output of the filter between the first and second input signals. At least one of the first and second input signals is a time-varying analog signal. The smooth transition between the first and second input signals has a shape determined by pulse width and frequency characteristics of pulses output by the circuit to alternately actuate the first and second switching circuits. The shape may include a linear ramp, an S-shaped curve, a parabolic curve and a hyperbolic curve.

### PRIORITY CLAIM

The present application is a translation of and claims priority from Chinese Application for Patent No. 200810176191.1 of the same title filed Nov. 14, 2008, the disclosure of which is hereby incorporated by reference.

### BACKGROUND OF THE INVENTION

1. Technical Field of the Invention

The present invention relates to method and apparatus for switching smoothly between two different analog input signals.

2. Description of Related Art

Reference is made to FIG. 1 which illustrates a prior art circuit used for switching between two input analog signals S1 and S2 to generate an output signal O. The circuit utilizes two switches which in a preferred implementation are MOS transistor devices. The first transistor switch T1 has its conduction path (source-drain circuit) connected between an input node receiving the first analog signal S1 and a common node N from which output signal O is generated. The second transistor switch T2 has its conduction path (source-drain circuit) connected between an input node receiving the second analog signal S2 and the common node N from which output signal O is generated. A control signal CTRL alternately controls actuation of the first and second transistor switches T1 and T2. The control signal CTRL is directly applied to the control terminal (gate) of the first transistor switch T1, and is inverted by an inverter device prior to application to the control terminal (gate) of the second transistor switch T2.

When control signal CTRL is in a first logic state, the first transistor switch T1 is turned on and the first analog signal S1 is passed through the conduction path (source-drain circuit) to the common node N for output as the output signal O. At this point in time, the inverter applies the control signal CTRL in a second logic state to the second transistor switch T2, which causes the second transistor switch T2 to turn off.

Conversely, when control signal CTRL is in the second logic state, the inverter applies the control signal CTRL in the first logic state to the second transistor switch T2. The second transistor switch T2 is turned on and the second analog signal S2 is passed through the conduction path (source-drain circuit) to the common node N for output as the output signal O. At this point in time, the control signal CTRL in the second logic state is applied to the first transistor switch T1, which causes the first transistor switch T1 to turn off.

Reference is now made to FIG. 2 which illustrates a timing diagram showing operation of the circuit of FIG. 1. When the control signal CTRL is in a first state (for example, logic low), the output signal is at a voltage level associated with the first input signal. Conversely, when the control signal CTRL is in a second state (for example, logic high), the output signal is at a voltage level associated with the second input signal. Although the output signal (which is switched between the two input analog signals S1 and S2) is shown to have constant voltage, it will be understood that the input analog signals S1 and S2 can, and most likely will, be time-varying signals.

It will be noted that at the time of the state change in the control signal CTRL, and if two input analog signals S1 and S2 are at different voltage levels, there will be a discontinuity (or a step or voltage jump) in the output signal. In some applications, this discontinuity can cause problems. For example, in an audio application wherein the output signal O is eventually applied to a speaker the voltage jump of the output signal O between the voltage levels of the two input analog signals S1 and S2 will create a “pop” noise. It would be desirable if a smooth transition between the voltage levels of the two input analog signals S1 and S2 could be achieved.

Reference is now made to FIG. 3 which illustrates another prior art circuit used for switching between two input analog signals S1 and S2 to generate an output signal O. The circuit utilizes two switching sets, each set including a plurality of MOS transistor devices and a plurality of resistors, in connection with selectively switching the two input analog signals S1 and S2 to the common node N from which output signal O is generated.

A first switching set associated with the first analog signal S1 is comprised of a plurality of pass paths, wherein each pass path is made from a series connected MOS transistor and resistor. These pass paths are connected in parallel with each other between an input node receiving the first analog signal S1 and a common node N from which output signal O is generated. The resistors in the first switching set are binary weighted.

A second switching set associated with the second analog signal S1 is comprised of a plurality of pass paths, wherein each pass path is made from a series connected MOS transistor and resistor. These pass paths are connected in parallel with each other between an input node receiving the second analog signal S2 and the common node N from which output signal O is generated. The resistors in the second switching set are also binary weighted in the same way as the resistors of the first switching set.

A different control signal is applied to the control terminal (gate) of each of the transistor switches in the first and second switching sets. These gate control signals are generated by a logic control circuit which receives at its input a control signal CTRL. This logic control circuit is typically implemented as a counter circuit. Responsive to a state change in the received control signal CTRL, the logic control circuit selectively changes the logic state of the output gate control signals over a transition period of time. The logic control circuit, through its counter circuit, essentially converts the step transition of the control signal CTRL into a plurality of small step changes in the output signal O between the two input analog signals S1 and S2.

Reference is now made to FIG. 4 which illustrates a timing diagram showing operation of the circuit of FIG. 3. When the control signal CTRL is in a first state (for example, logic low), the output signal is at a voltage level associated with the first input signal S1. At the time of the state change in the control signal CTRL, it will be noted that the output signal O does not immediately jump to the voltage level of the second input signal S2. Rather, over the transition period of time there is a stair-step transition from the voltage of first input signal S1 to the voltage of the second input signal S2. The number of steps in this transition is governed by the number of transistor switches in the first and second switching sets, the binary weighting of the resistors and the implementation of the counter circuit.

While this circuit provides for a smoother transition between the voltage levels of the two input analog signals S1 and S2, there are a number of disadvantages associated with the circuit of FIG. 3. First, if implemented an integrated circuit, the need for binary weighted resistors causes an unacceptable increase in circuit size (area). Second, there is an unwanted tone created in the output signal O which is caused by the fixed period between each small step in the stair-step transition between the voltages of first and second input signals S1 and S2. Third, in the event there is some impedance between the voltages of the first and second input signals S1 and S2, then unless the impedance of the counter must be larger there will be an error introduced into the small steps. Lastly, the shape of the transition between the voltages of first and second input signals S1 and S2 cannot be easily controlled/varied.

A need accordingly exists for a circuit and method to smoothly transition between two analog input signals with a desired transition.

### SUMMARY

In an embodiment, a device comprises: a first switching circuit having an input for receiving a first input signal; a second switching circuit having an input for receiving a second input signal; a node connected to receive outputs from both the first and second switching circuits; a filter having an input for receiving an unfiltered signal from the node and having an output; and a circuit which alternately actuates the first and second switching circuits during a transition time period so as to smoothly transition the output of the filter between the first and second input signals.

In an embodiment, a device comprises: a first switching circuit having an input for receiving a first input signal; a second switching circuit having an input for receiving a second input signal; a node connected to receive outputs from both the first and second switching circuits; and a circuit which alternately actuates the first and second switching circuits during a transition time period so as to smoothly transition an output signal from the node between the first and second input signals.

In an embodiment, a device comprises: a first switching circuit for selectively passing a first input signal towards an output; a second switching circuit for selectively passing a second input signal towards the output in a manner alternative to the first switching circuit; and a control circuit which controls the alternative selective passing of the first and second input signals during a transition period of time defined by a train of pulses. Each pulse in the train has an on time for the first switching circuit and an on time for the second switching circuit such that: during a first half of the transition period of time the on time for the second switching circuit is fixed in length and the on time for the first switching circuit gradually decreases in length; and during a second half of the transition period of time the on time for the first switching circuit is fixed in length and the on time for the second switching circuit gradually increases in length.

In an embodiment, a device comprises: a first MOS transistor having a source-drain circuit coupled to receive a first input signal, the first MOS transistor having a first control gate; a second MOS transistor having a source-drain circuit coupled to receive a second input signal, the second MOS transistor having a second control gate; a common node coupled to receive outputs from the source-drain circuits of the first and second MOS transistors; a pulse generator circuit outputting a transition pulse train applied to the first control gate; and an inverter circuit receiving the transition pulse train and applying its logical inversion to the second control gate. The transition pulse train has pulse width and frequency characteristics so as to smoothly transition an output signal from the common node between the first and second input signals.

In an embodiment, a method comprises: selectively passing a first input signal towards an output; selectively passing a second input signal towards the output in a manner alternative to the first input signal; and controlling the alternative selectively passing of the first and second input signals during a transition period of time defined by a train of pulses having pulse width and frequency characteristics so as to smoothly transition an output signal between the first and second input signals.

### BRIEF DESCRIPTION OF THE DRAWINGS

Other objectives, features and advantages of the invention will become apparent upon reading the following description, presented solely by way of non-limiting example and with reference to the appended drawings, in which:

FIG. 1 illustrates a prior art circuit used for switching between two input analog signals to generate an output signal;

FIG. 2 illustrates a timing diagram showing operation of the circuit of FIG. 1;

FIG. 3 illustrates another prior art circuit used for switching between two input analog signals to generate an output signal;

FIG. 4 illustrates a timing diagram showing operation of the circuit of FIG. 3;

FIG. 5 illustrates a circuit for smoothly switching between two input analog signals to generate an output signal; and

FIG. 6 illustrates a timing diagram showing operation of the circuit of FIG. 5.

### DETAILED DESCRIPTION OF THE DRAWINGS

Reference is made to FIG. 5 which illustrates a circuit for smoothly switching between two input analog signals S1 and S2 to generate an output signal O. The circuit utilizes two switches which in a preferred implementation are MOS transistor devices. The first transistor switch T1 has its conduction path (source-drain circuit) connected between an input node receiving the first analog signal S1 and a common node N. The second transistor switch T2 has its conduction path (source-drain circuit) connected between an input node receiving the second analog signal S2 and the common node N. A low pass filter circuit is connected between the common node N and an output node from which output signal O is generated. A transistor control terminal (gate) drive control signal DCTRL alternately controls actuation of the first and second transistor switches T1 and T2. The gate drive control signal DCTRL is directly applied to the control terminal (gate) of the first transistor switch T1, and is inverted by an inverter device prior to application to the control terminal (gate) of the second transistor switch T2.

When gate drive control signal DCTRL is in a first logic state, the first transistor switch T1 is turned on and the first analog signal S1 is passed through the conduction path (source-drain circuit) to the common node N for output as the output signal O. At this point in time, the inverter applies the gate drive control signal DCTRL in a second logic state to the second transistor switch T2, which causes the second transistor switch T2 to turn off.

Conversely, when gate drive control signal DCTRL is in the second logic state, the inverter applies the gate drive control signal DCTRL in the first logic state to the second transistor switch T2. The second transistor switch T2 is turned on and the second analog signal S2 is passed through the conduction path (source-drain circuit) to the common node N for output as the output signal O. At this point in time, the gate drive control signal GDCTRL in the second logic state is applied to the first transistor switch T1, which causes the first transistor switch T1 to turn off.

The gate drive control signal DCTRL is generated by a pulse generator circuit which receives at its input a control signal CTRL. The control signal CTRL is a logic signal whose value specifies which of the two input analog signals S1 and S2 to supply the output signal O. For example, if the control signal CTRL is logic low, then this indicates to the pulse generator circuit that the gate drive control signal DCTRL applied to the first and second transistor switches T1 and T2 should result in the first analog signal S1 being passed as the output signal O. Conversely, if the control signal CTRL is logic high, then this indicates to the pulse generator circuit that the gate drive control signal DCTRL applied to the first and second transistor switches T1 and T2 should result in the second analog signal S2 being passed as the output signal O. The gate drive control signal DCTRL is generated by the pulse generator circuit facilitates switching between the two input analog signals S1 and S2 to supply the output signal O in a smooth manner.

FIG. 6 illustrates a timing diagram showing operation of the circuit of FIG. 5. Although the output signal (which is switched between the two input analog signals S1 and S2) is shown to have constant voltage, it will be understood that the input analog signals S1 and S2 can, and most likely will, be time-varying signals.

Assume that the control signal CTRL is in a first state (for example, logic low) and the output signal has the voltage level associated with the first input signal S1. The pulse generator circuit will be generating a constant gate drive control signal DCTRL having the proper logic state to turn on transistor switch T1 and turn off transistor switch T2 so as to pass the first input signal S1 to common node N, through the low pass filter and generate the output signal O.

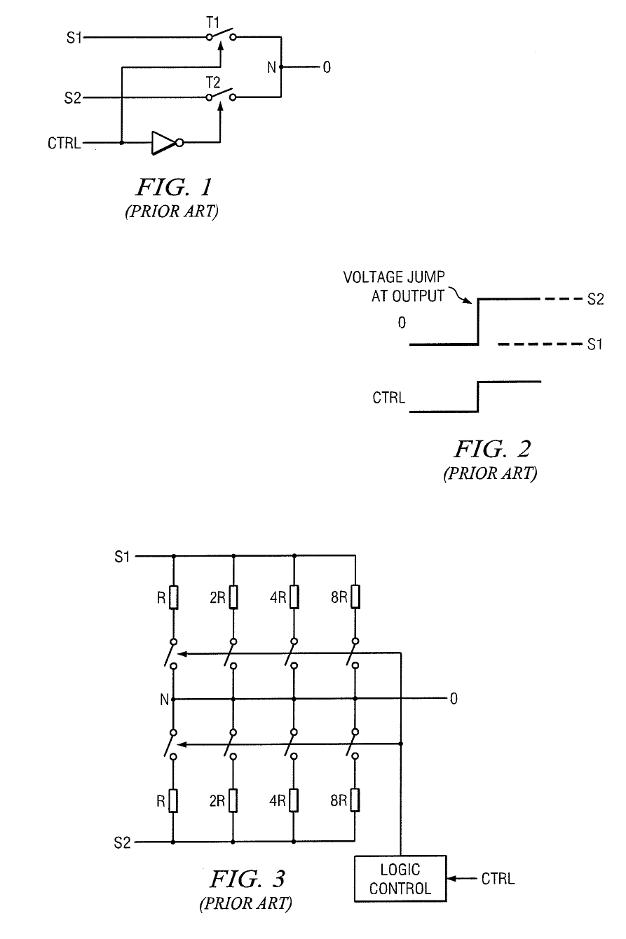

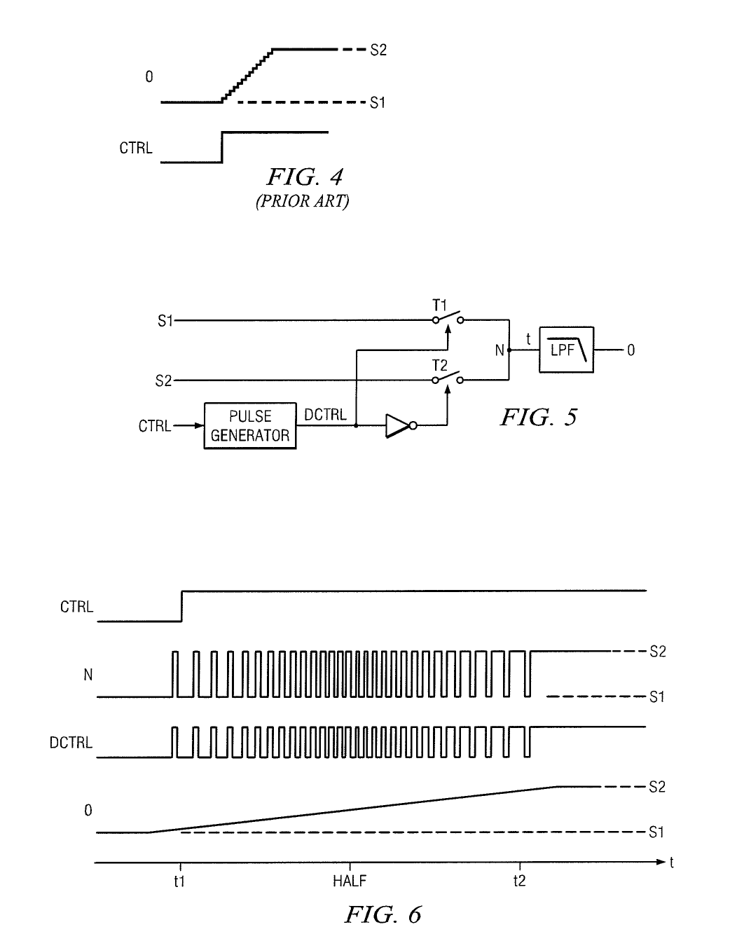

At first instant in time t1, the control signal CTRL switches from the first state to a second state (for example, logic high) indicating a desire to switch the output O from the voltage level associated with the first input signal S1 to the voltage level associated with the second input signal S2. Contrary to the process shown in connection with prior art FIGS. 1 and 2, this switch in signals at the output is not instantaneous.

The pulse generator circuit responds to the state change of control signal CTRL by generating a stream of pulses over a transition time period t1-t2, having one or more of a different pulse width and/or a different frequency, as the gate drive control signal DCTRL. During the transition time period t1-t2, the alternating logic state of the gate drive control signal DCTRL causes the voltage levels associated with the first and second input signals S1 and S2 to be alternately passed to common node N, through the low pass filter and generate the output signal O.

As shown in FIG. 6, towards the front end of the transition time period t1-t2, the pulse generator circuit generates the gate drive control signal DCTRL to have pulses which emphasize the logic state which would cause passing of the first input signal S1 to common node N. Thus, the pulse is wider with respect to the logic state associated with passing first input signal S1. The width of each pulse with respect to the logic state associated with passing second input signal S2 is the same during a first half of the transition time period t1-t2, but the width of each pulse with respect to the logic state associated with passing first input signal S1 is gradually decreasing.

Moving towards the center portion of the transition time period t1-t2, the pulse generator circuit generates the gate drive control signal DCTRL to have pulses where the first and second input signals S1 and S2 are relatively evenly (or equally) passed to common node N.

Towards the back end of the transition time period t1-t2, the pulse generator circuit generates the gate drive control signal DCTRL to have pulses which emphasize the logic state which would cause passing of the second input signal S2 to common node N. Thus, the pulse is becomes wider with respect to the logic state associated with passing second input signal S2. The width of each pulse with respect to the logic state associated with passing first input signal S1 is the same during a second half of the transition time period t1-t2, but the width of each pulse with respect to the logic state associated with passing second input signal S2 is gradually increasing.

At the end of the transition time period occurring at instant at time t2, the pulse generator circuit will be generating a constant gate drive control signal DCTRL having the proper logic state to turn off transistor switch T1 and turn on transistor switch T2 so as to pass the second input signal S2 to common node N, through the low pass filter and generate the output signal O.

The low pass filter functions to filter out high frequency noise from the signal at common node N. This high frequency noise is introduced by the switching on and off of the transistor switches T1 and T2 during the transition time period t1-t2.

It will be recognized that the configuration of the pulses for the gate drive control signal DCTRL shown in FIG. 6 is only an example of the control pulse waveform for the transition time period t1-t2. Alternative control pulse waveforms could be generated through the use of a pulse generator circuit configured for pulse-width modulation (PWM) or delta-sigma modulation.

The transition of the output signal O between the two input analog signals S1 and S2 is shown in FIG. 6 to be a linear ramp. It will be recognized that the shape of the transition can be controlled and selected by adjusting the control pulse waveform generated by the pulse generator circuit. The transition shape could, alternatively, be S-shaped, parabolic, hyperbolic or any other selected smooth curve function.

The two input analog signals S1 and S2 can take on any form including fixed (static) voltages, dynamic voltages, or any combination thereof.

Although illustrated as switching between two input analog signals S1 and S2, it will be understood that the techniques described herein are equally applicable to a scenario wherein one would desire to switch among and between any number of analog input signals. In such situation, one switching transistor would be provided for each input signal, and the gate drive control signal DCTRL would generate a separate transistor control signal for each included switching transistor.

The circuit of FIG. 5 is preferably implemented as an integrated circuit (for example, as a discrete integrated circuit or in a multi-function integrated circuit device).

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A device, comprising:
a first switching circuit having an input for receiving a first input signal;
a second switching circuit having an input for receiving a second input signal;
a node connected to receive outputs from both the first and second switching circuits; and
a circuit which alternately actuates the first and second switching circuits during a transition time period so as to smoothly transition an output signal from the node between the first and second input signals.

2. The device of claim 1 further comprising a low pass filter having an input for receiving the output signal from the node.

3. The device of claim 1 wherein the first and second input signals are time-varying analog signals.

4. The device of claim 1 wherein at least one the first and second input signals is a time-varying analog signal.

5. The device according to claim 1 wherein the first and second switching circuits are transistors.

6. The device of claim 5 wherein the transistors are MOS transistors.

7. The device of claim 1 wherein the smooth transition between the first and second input signals has a shape determined by pulse width and frequency characteristics of pulses output by the circuit to alternately actuate the first and second switching circuits.

8. The device of claim 7 wherein the shape of the smooth transition is a linear ramp.

9. The device of claim 7 wherein the shape of the smooth transition is an S-shaped curve.

10. The device of claim 7 wherein the shape of the smooth transition is a parabolic curve.

11. The device of claim 7 wherein the shape of the smooth transition is a hyperbolic curve.

12. A device, comprising:
a first switching circuit for selectively passing a first input signal towards an output;
a second switching circuit for selectively passing a second input signal towards the output in a manner alternative to the first switching circuit;
a control circuit which controls the alternative selective passing of the first and second input signals during a transition period of time defined by a train of pulses, wherein each pulse in the train has an on time for the first switching circuit and an on time for the second switching circuit such that:
during a first half of the transition period of time the pulse on time for the second switching circuit is fixed in length and the pulse on time for the first switching circuit gradually decreases in length; and
during a second half of the transition period of time the pulse on time for the first switching circuit is fixed in length and the pulse on time for the second switching circuit gradually increases in length.

13. The device of claim 12 further comprises a filter for filtering a signal received from the output.

14. The device of claim 12 wherein at least one the first and second input signals is a time-varying analog signal.

15. The device according to claim 12 wherein the first and second switching circuits are transistors.

16. A device, comprising:
a first MOS transistor having a source-drain circuit coupled to receive a first input signal, the first MOS transistor having a first control gate;
a second MOS transistor having a source-drain circuit coupled to receive a second input signal, the second MOS transistor having a second control gate;
a common node coupled to receive outputs from the source-drain circuits of the first and second MOS transistors;
a pulse generator circuit outputting a transition pulse train applied to the first control gate;
an inverter circuit receiving the transition pulse train and applying its logical inversion to the second control gate;
wherein the transition pulse train has pulse width and frequency characteristics so as to smoothly transition an output signal from the common node between the first and second input signals.

17. The device of claim 16 wherein each pulse in the transition pulse train has an on time for actuating the first MOS transistor and an on time for actuating the second switching circuit as defined by the pulse width and frequency characteristics such that:
during a first half of a transition period of time defined by a length of the transition pulse train, the pulse on time for actuating the second MOS transistor is fixed in length and the pulse on time for actuating the first MOS circuit gradually decreases in length; and
during a second half of the transition period of time the pulse on time for actuating the first MOS transistor is fixed in length and the pulse on time for actuating the second MOS transistor gradually increases in length.

18. The device of claim 16 further comprising a low pass filter having an input for receiving the output signal from the common node.

19. The device of claim 16 wherein the smooth transition between the first and second input signals has a shape determined by the pulse width and frequency characteristics.

20. The device of claim 19 wherein the shape of the smooth transition is a linear ramp.

21. The device of claim 19 wherein the shape of the smooth transition is a curve.

22. A method, comprising:
selectively passing a first input signal towards an output;
selectively passing a second input signal towards the output in a manner alternative to the first input signal;
controlling the selectively passing of the first and second input signals in an alternating manner during a transition period of time defined by a train of pulses having pulse width and frequency characteristics so as to smoothly transition an output signal between the first and second input signals.

23. The method of claim 22 wherein each pulse in the transition pulse train has an on time for actuating the first MOS transistor and an on time for actuating the second switching circuit as defined by the pulse width and frequency characteristics, and controlling comprises:
during a first half of a transition period of time defined by a length of the transition pulse train, controlling the pulse on time for selectively passing the second input signal to be fixed in length and the pulse on time for selectively passing the first input signal to gradually decrease in length; and
during a second half of the transition period of time, controlling the pulse on time for selectively passing the first input signal to be fixed in length and the pulse on time for selectively passing the second input signal to gradually increase in length.

24. The method of claim 22 wherein each pulse in the transition pulse train has an on time for actuating the first MOS transistor and an on time for actuating the second switching circuit as defined by the pulse width and frequency characteristics, and controlling comprises:
decreasing the pulse on time for selectively passing the first input signal over the transition period of time; and
increasing the pulse on time for selectively passing the second input signal over the transition period of time.

25. The method of claim 22 further including filtering the output signal.
